(19) United States
(12) Patent Application Publication
(10) Pub. No.: US 2006/0009029 A1
(43) Pub. Date: Jan. 12, 2006

(54) Wafer level through-hole plugging using mechanical forming technique

(75) Inventors: Wong EE Hua, Signapore (SG); Chong Ser Choong, Singapore (SG); Ma Yiyi, Singapore (SG)

Correspondence Address: STEPHEN B. ACKERMAN, 28 DAVIS AVENUE, POUGHKEEPSIE, NY, 12603, US

(73) Assignee: Agency For Science, Technology And Research

(21) Appl. No.: 11/112,984

(22) Filed: Apr. 22, 2005

Related U.S. Application Data
(60) Provisional application No. 60/585,660, filed on Jul. 6, 2004.

(51) Int. Cl. H01L 21/4763

(52) U.S. Cl. 438/637; 438/675

(57) ABSTRACT

A wafer is provided having at least one through-hole therein. The at least one through-hole is filled with one or more conductive balls. Thereafter, the wafer is compressed wherein the one or more conductive balls form a conductive plug in the at least one through-hole. After forming the conductive plug in one or more wafers, the wafers can be joined to form a three-dimensional system.

This application claims priority to U.S. Provisional Patent Application Ser. No. 60/585,660, filed on Jul. 6, 2004, which is herein incorporated by reference in its entirety.

### BACKGROUND OF THE INVENTION

1) Field of the Invention

This invention relates generally to a technique to generate through-hole interconnection at the wafer level, suitable for implementing into 3-D packaging involving silicon-to-silicon stacking or in MEMS packaging involving silicon-to-silicon or silicon-to-glass stacking. The invention is a clean, simple, robust, high throughput, high flexibility, low cost wafer level processing technique. More specifically, the invention describes the technique and processes of forming multiples of through-silicon interconnections in a wafer using a mechanical forming technique.

(2) Description of the Related Art

The market demand for smaller, faster, and cheaper product has always been the main driving force behind higher density, higher speed, and more efficient packaging technologies. The drive for high density packaging has led naturally to 3-dimensional packaging which further offers the potential for reduced signal transmission length, a critical element for high speed performance, as well as a wafer level packaging process, a critical element to reduce manufacturing cost.

Three dimensional packaging may be achieved through (i) stacking of package onto package where interconnections are made between the packages using exterior routing; (ii) stacking of chip onto chip where interconnections are made between the chips using exterior routing—wire bond or flip chip; or (iii) stacking of chip-to-chip at wafer level where interconnections between the stacked chips are achieved using through-chip interconnection. The first two technologies require only a simple extension of the standard packaging technology, but offer little, if any, advantage in signal transmission speed and manufacturing cost. Through-chip interconnection not only offers the shortest possible signal path, but also provides a wafer-level packing process. This requires an enabling technology—through-silicon interconnection, which has been an area of active research and development due to its vast potential.

The common step in through-silicon interconnection technology is the generation of through-silicon holes, usually at the wafer level. The technology of depositing an interconnection into the through-hole via has been the main research and developmental focus. The most common technology for achieving through-silicon interconnection is electroplated through-via, with copper as the most common metal. This technology is discussed in the article “Wafer process and issues of through electrode in Si wafer using Cu damascene for three dimensional chip stacking,” by M. Hashino et al, Proc. Int. Interconnnect Technology, 2002, pp. 75-77, and in U.S. Patent publication 2004/0077154A1, and in U.S. Pat. Nos. 6,458,696 and 6,599,778. This technology offers the advantage of fine pitch through the use of front-end lithography and chemical-mechanical polishing processes. While this technology has found special applications in super fine pitch interconnection (<50 μm) between wafers, the expensive processes cannot be justified for interconnection that does not require such fine pitch. For this, alternative low cost technologies have been developed. The reported technologies usually involve the use of viscous conductive materials, usually solder, but may be conductive polymer or a mixture, which are either printed (as in U.S. patent application Ser. No. 10/746,199), vacuum drawn (as in “Filling the via hole of IC by VPES (vacuum printing encapsulating system) for stack chip”, by A. Okuno et al, ECTC, 2002, pp. 1444-1448), or jetted (as in U.S. Pat. No. 6,589,593) into the through-hole. Printing a consistent amount of solder or conductive paste into a through-hole of standard aspect ratio has not been easy. This has prompted the use of vacuum, aided with heat, to assist the flow of the molten solder into the via. But handling of molten solder at the wafer level can be messy and the risk of wafer contamination is high. Jetting a solid ball or molten drop of solder into the via offers a consistent means of deposition, but suffers from the obvious disadvantage of either slow through-put due to single deposition or expensive investment into multiple jetting heads.

U.S. Pat. No. 6,252,779 discloses a method for joining electronic devices such as integrated circuits to vias in a substrate. A solder ball attached to an electronic device is joined to a contact pad of a via by a low melting temperature solder into the via hole. The opening of the via is plugged using a solder ball or a compressed length of a wire material. However, the via's wall surface is covered by wettable metal and it is only applicable to organic substrates.

U.S. Pat. No. 5,915,756 provides a method of filling via holes between a lower conductive layer and an upper conductive layer whereby the hole is filled by the lower conductive layer. By optimizing conditions such as compressive stress and temperature during the deposition of the various layers, the method of this patent ensures that at a predefined temperature, compressive force on the lower conductive layer causes hillocks to form inside the via holes. This process requires precise manipulation of the via material itself to form the interconnects between the layers.

### SUMMARY OF THE INVENTION

A principal object of the present invention is to provide an effective and very manufacturable method of fabricating a through-silicon interconnection.

Another object of the invention is to provide a process for fabricating a through-silicon interconnection of moderate pitch using compression techniques.

Yet another object is to provide a process for fabricating a through-silicon interconnection using conductive balls of deformable material.

A further object of the invention is to provide a method for fabricating a through-silicon interconnection using conductive balls of a hard material in combination with conductive balls of deformable material.

A still further object is to provide a method for forming stacked wafers.

In accordance with the objects of this invention, a method of fabricating a through-silicon interconnection is achieved. A wafer is provided having at least one through-hole therein. The through-hole is filled with one or more conductive balls. Thereafter, the wafer is compressed wherein the one or more conductive balls form a conductive plug in the through-hole.

Also in accordance with the objects of the invention, a method of forming a three-dimensional system is achieved. A first wafer and one or more second wafers are provided, each having at least one through-hole therein. The through-hole of each wafer is filled with one or more conductive balls. Thereafter, each of the wafers is compressed wherein the one or more conductive balls form a conductive plug in the through-hole of each of the wafers. Thereafter, the first wafer and one or more second wafers are joined.

Also in accordance with the objects of the invention, a mechanical compression device is achieved. The device comprises a top and a bottom compression platform and means for compressing a wafer between the top and bottom compression platforms wherein the top and bottom compression platforms are shaped to form a depression or a protrusion on a top or bottom of a conductive plug formed in a through-hole in the wafer.

### BRIEF DESCRIPTION OF THE DRAWINGS

In the accompanying drawings forming a material part of this description, there is shown:

FIGS. 1A through 1D schematically illustrate in cross-sectional representation a process sequence of a preferred embodiment of the present invention.

FIG. 2 schematically illustrates in cross-sectional representation a typical design of through-hole via for better anchoring of the formed plug of the present invention.

FIGS. 3A through 3D illustrate in cross-sectional representation some sample designs of plug depression and protrusion of the present invention.

FIGS. 4A and 4B illustrate in cross-sectional representation some combinations of conductive balls with different materials in the present invention.

FIGS. 5A1, 5A2, 5B1, and 5B2 illustrate in cross-sectional representation some combinations of conductive balls with different hardness in the present invention.

FIGS. 6A through 6D illustrate in cross-sectional representation an alternative method to compress the conductive balls in two stages.

### DESCRIPTION OF THE PREFERRED EMBODIMENTS

The present invention offers the method and processes of achieving a through-silicon interconnection of moderate pitch using compression techniques. Several inventive embodiments of the present invention are described below.

The method begins with a wafer that has been pre-processed with the designed quantity and position of through-holes of designed dimension, geometry, and with suitable treatment (such as a diffusion barrier, for example) on its wall. Each through-hole on the wafer is deposited with the designed diameter and quantity of conductive balls using the standard shake and drop technique. The conductive balls are then compressed, whereby they flatten and fill the through-hole, forming a conductive plug.

The wafer with conductive plugs may then be (i) stacked onto correspondingly plugged wafer/s, before being singulated into stacked chips, or (ii) cut into a carrier for mounting chips to become a sub-module, which is then stacked onto correspondingly plugged sub-module/s to form a 3-D system.

The current invention offers the following attractive features:
Low cost—achieved through the use of simple and robust back-end wafer level processes that allow high throughput at low operation and material cost.
High flexibility—achieved through design flexibility in the geometry of the through-hole as well as the material (and combination). If desirable, the process may be applied at a selected domain on the wafer.
High flatness and co-planarity—inherent in the mechanical forming which mirrors the high quality of the forming tool.
High aspect ratio—achieved through sequential ball deposition and compression.
High reliability—achieved through (i) built-in compressive residue stress between the formed plug and the wall of the through-hole; (ii) good bonding between the formed plug and the wall of the through-hole from elaborated temperature compression.

Other aspects and advantages of the invention will become apparent from the following detailed description, taken in conjunction with the accompanying drawings, illustrating by way of example the principles of the invention.

A method and device to form a through-silicon plug for interconnection are provided. In the following description, numerous specific details are set forth in order to provide a thorough understanding of the present invention. It will be understood, however, by one skilled in the art, that the present invention may be practiced without some or all of these specific details. In other instances, well known process operations have not been described in detail in order not to unnecessarily obscure the present invention.

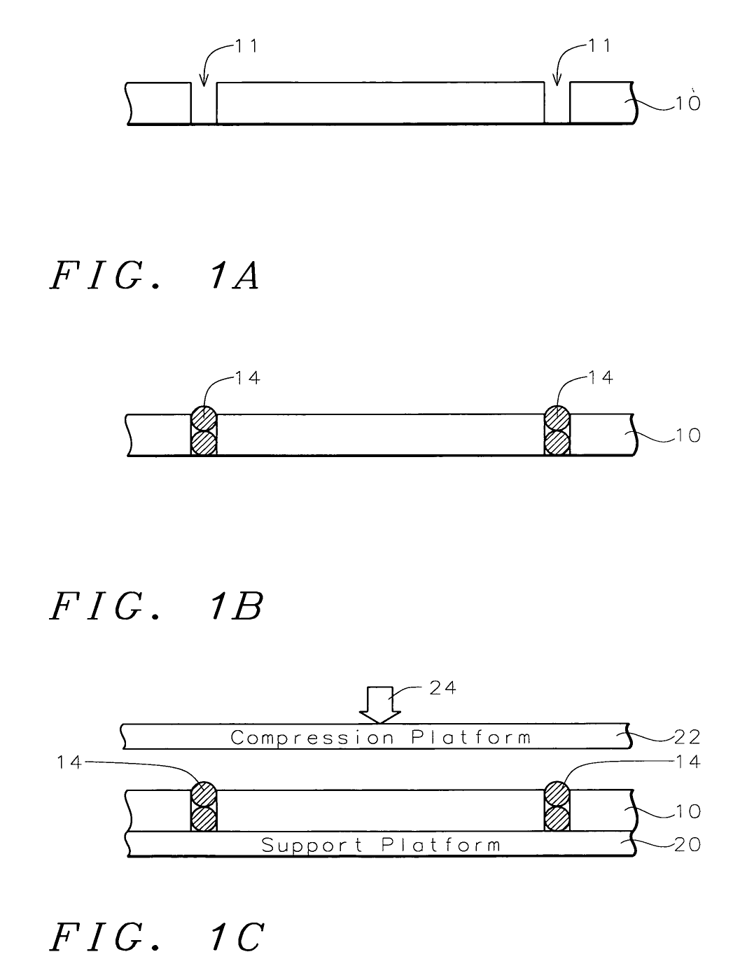

The process sequence is depicted in FIGS. 1A through 1D. Referring now more particularly to FIG. 1A, there is shown wafer 10 with designed through-hole vias 11. The designed quantity and position of through-holes of the designed dimension and geometry are formed by appropriate patterning or milling techniques. Pre-treatment may be applied to the walls of the through-hole vias. For example, a diffusion barrier may be formed on the wall of the through-hole vias. For example, diffusion barrier 16 is shown on the sidewalls of the through-hole vias in FIG. 1D. It will be understood that the diffusion barrier 16, if used, will be present at the stage shown in FIG. 1A.

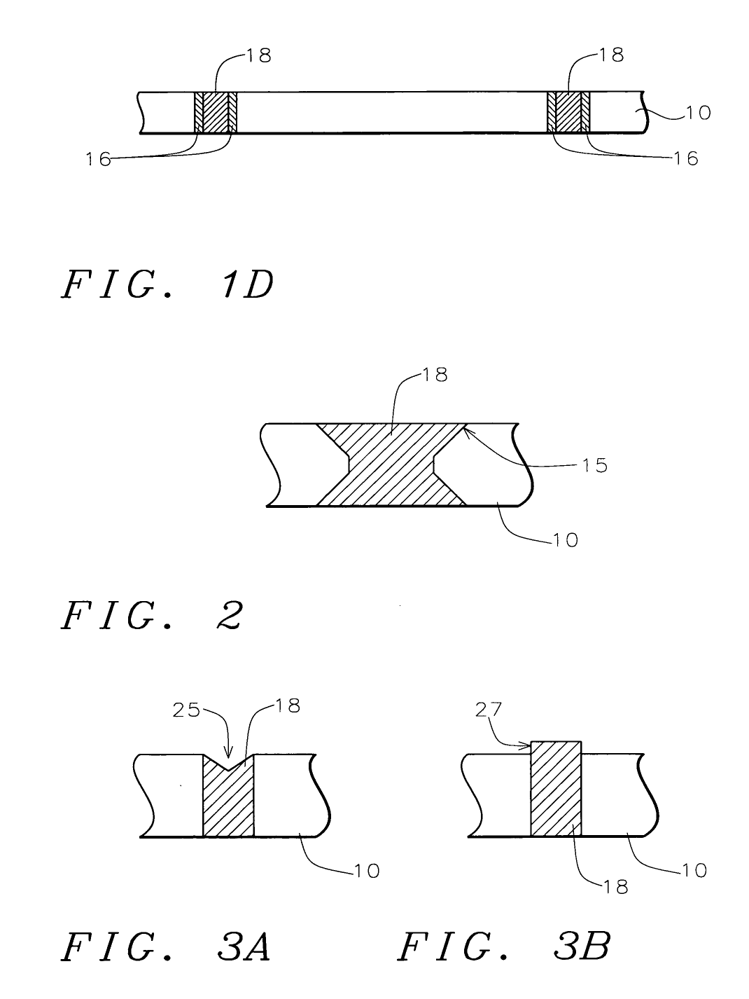

The through-hole on the wafer may be designed with suitable chamfering or other geometries that provide anchoring to the formed conductive plug. A typical design of a through-hole via for better anchoring of the formed plug 18 is depicted in FIG. 2. The chamfer 15 on the silicon can be made with a standard etching process. It will be understood that other designs for dimension and geometry of the through-hole vias can be utilized.

Next, as shown in FIG. 1B, conductive balls 14 having a designed diameter and quantity are deposited into the through-hole vias using the standard shake and drop technique. The conductive balls may be made of deformable metals such as solder, copper, silver, etc. or any material or composite that is conductive and deformable, such as the composite of graphite or silver particulates in the matrix of a compressible polymer. Conductive balls made of hard metals may also be used in combination with those made of deformable materials. Conductive balls made of different materials may be filled into the through-hole in the designed quantity and sequence so as to achieve the desired effect.

Referring now to FIG. 1C, the wafer is put into a mechanical compression device. Force 24 is applied to the compression platform 22 to flatten the conductive balls 14 within the through-hole vias of the wafer 10 on the support platform 20. The flattening of the conductive balls may be performed at room or elevated temperature, but below the melting temperature of the conductive balls. Elevated temperature is used to either (i) improve the malleability of the conductive ball so as to minimize damage to the through-hole on the silicon or (ii) enhance the adhesion of the formed plug to the wall of the through-hole.

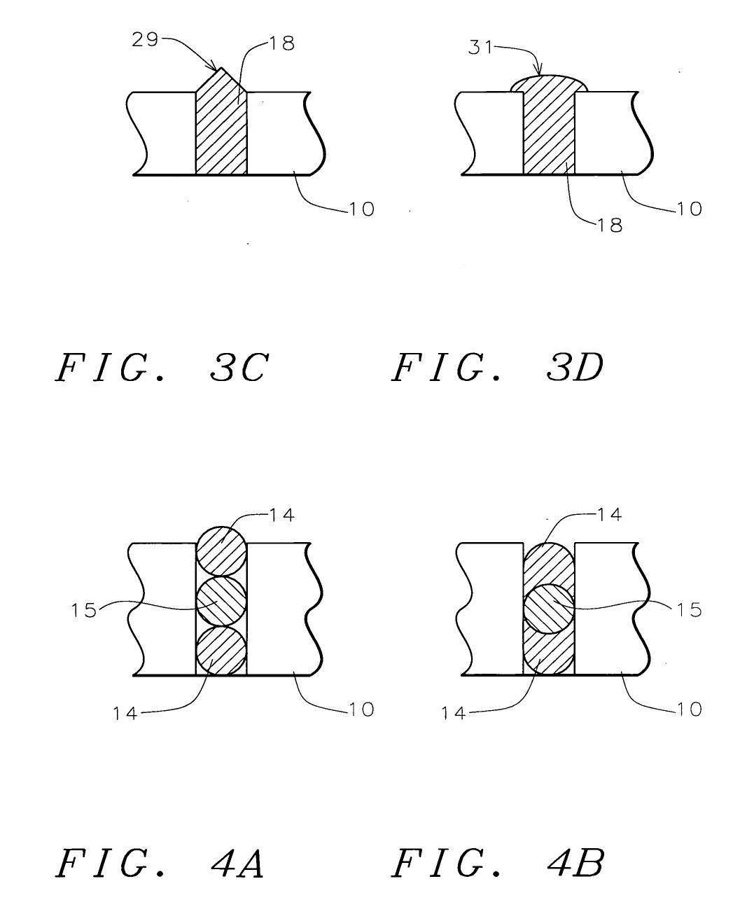

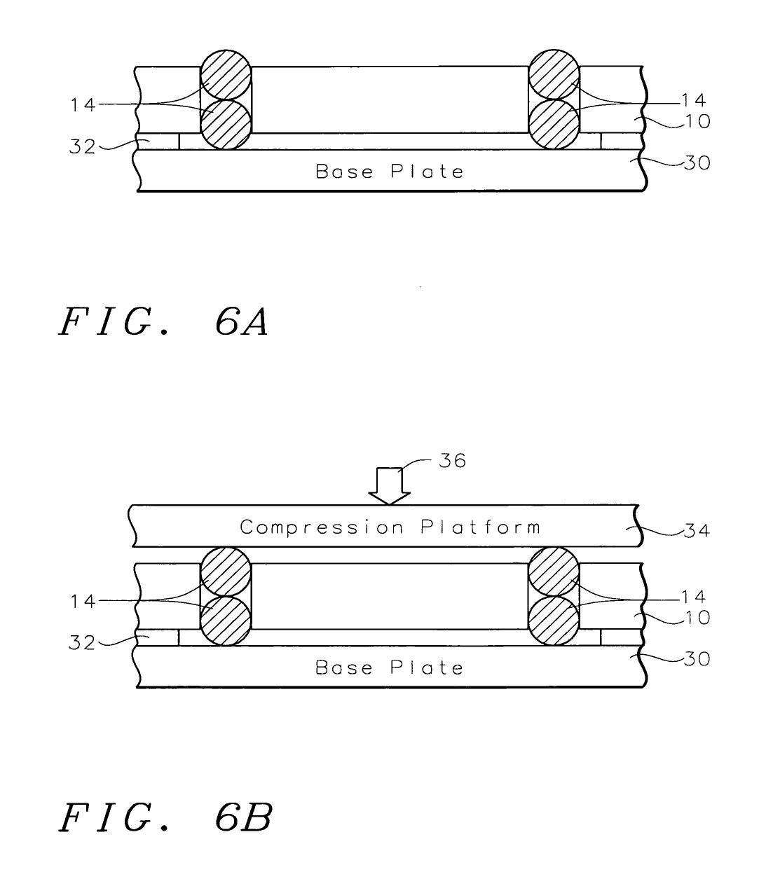

The size and geometry of the through-hole and the diameter and quantity of the conductive balls are so designed that the total volume of the conductive ball may be lesser, equal, or larger than that of the through-hole. Some designs of plug depression and protrusion are depicted in FIGS. 3A-3D. The formed plug depression and protrusion are formed by compression or support platforms that have the corresponding protrusion and depression, respectively. The depression and protrusion may be on one or both sides of the wafer. In the case of lesser volume, as shown in FIG. 3A, for example, the formed plug 18 will be below the surfaces of the wafer and the formed depression 25 will be shaped by the compression platforms to any geometry so as to provide the desired effects. In the case of equal volume, the formed plug 18 will be level with the surfaces of the wafer, as shown in FIG. 1D. In the case of larger volume, the formed plug 18 will protrude above the surfaces of the wafer and the protrusion may be shaped by the two compression platforms to any geometry so as to provide the desired effects, including, but not limited to, easy interconnection with the neighboring wafers. FIGS. 3B, 3C, and 3D show formed plugs 18 having differently shaped protrusions 27, 29, and 31, respectively. For example, a protrusion of pyramid shape made of hard metal may penetrate and interlock with the depression in the formed plug of the neighboring wafer made of more malleable material, as shown in FIG. 5A.

The deposition and the flattening of the conductive balls may be performed in successive sequence so as to achieve the desired aspect ratio. In such case, the in-process formed plug shall come with a depression for receiving a new round of conductive balls.

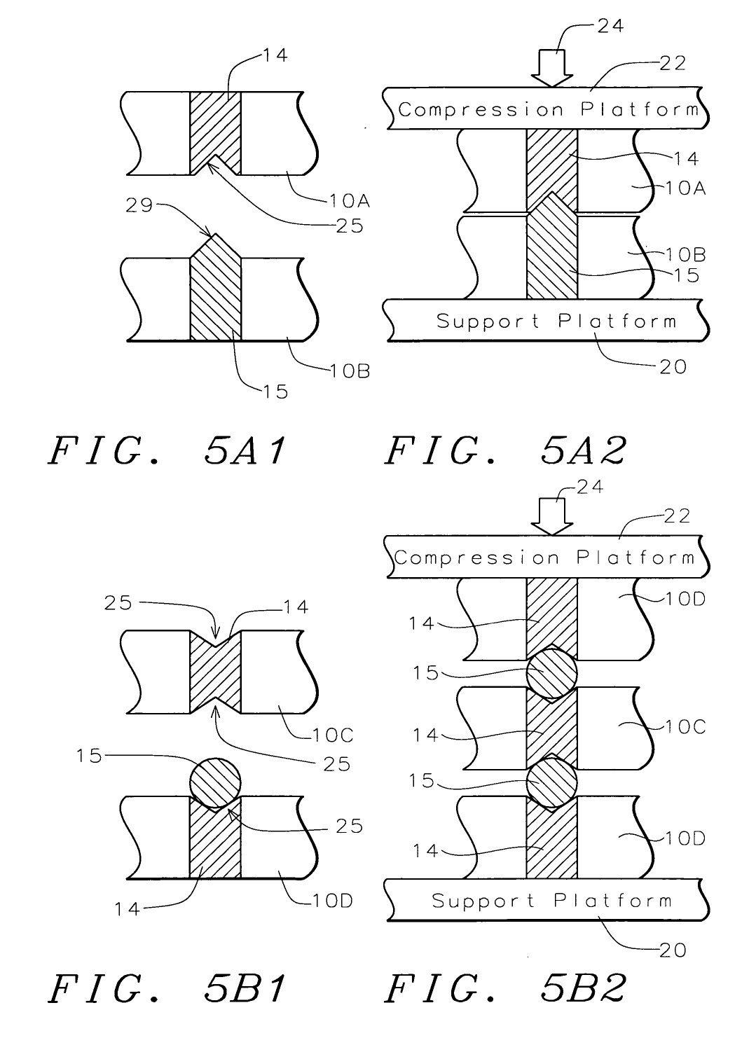

A typical combination of conductive balls with different materials is depicted in FIGS. 4A and 4B. For example, FIG. 4A shows conductive balls 14 of a soft material and conductive ball 15 of a hard material. FIG. 4B shows conductive ball 15 of a hard material surrounded by conductive ball 14 of a soft material.

FIG. 1D shows the finished product, the wafer 10 having formed plugs 18. As noted above, optional diffusion barrier 16 may have been formed on the sidewalls of the through-hole vias prior to deposition of the conductive balls 14. The wafer with conductive plugs may then be (i) stacked onto correspondingly plugged wafer/s, before being singulated into stacked chips, or (ii) cut into a carrier for mounting chips to become a sub-module, which is then stacked onto correspondingly plugged sub-module/s to form a 3-D system.

Post heating at a temperature below the melting temperature of any of the conductive materials may be applied to enhance diffusion bonding between the conductive balls and the wall of the through-hole; or in the case of a mechanically compressed stacked wafer, between the conductive plugs. Post heating may also be performed at a temperature above one or more of the melting temperatures of the conductive materials for maximum bonding.

The interconnection between wafers with leveled conductive plugs (as shown in FIG. 1D) may be achieved using a standard technique—through an additional volume of solder deposited onto one end of the conductive plugs. On the other hand, the interconnection between wafers with protruding plugs (as shown in FIGS. 3B-3D) may be achieved through mechanical compression.

A typical combination of plug materials with different hardness (and softening temperature) for interconnection of stacked wafers is depicted in FIGS. 5A and 5B. FIG. 5A1 shows wafer 10A having a softer conductive plug 14 with a depression 25 and a wafer 10B having a harder conductive plug 15 with a protrusion 29. FIG. 5A2 shows interconnection between the stacked wafers 10A and 10B achieved through penetration of the protrusion 29 of the conductive plug 15 made of harder material into the depression 25 of a conductive plug 14 made of softer material. FIG. 5B1 shows wafer 1 OC having a softer conductive plug 14 having a depression 25 on either side of its through-hole and wafer 10D having a softer conductive plug 14 having a depression 25 and a harder conductive ball 15. FIG. 5B2 shows interconnection between stacked wafers 10D, 1 OC, and 10D achieved through an additional conductive ball 15, made of harder material, that penetrates the depression 25 of the conductive plugs on both wafers. The hard conductive ball was deposited onto the depression of one of the wafers prior to stacking. Penetrative interconnection is achieved through mechanical compression, accompanied with heating if desirable. Post heating may be applied if desirable.

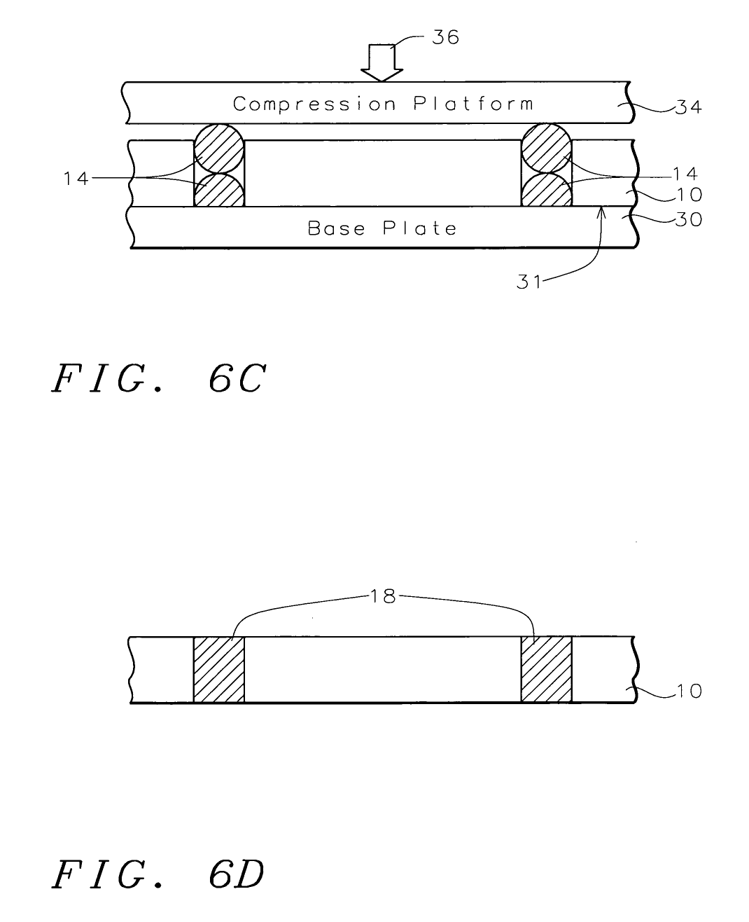

Two flattening stages can be used to achieve the filled via as shown in FIGS. 6A through 6D. Referring now to FIG. 6A, the wafer is put into a mechanical compression device having a base plate 30. Because of the protrusion of the balls 14, there is a small gap between the wafer and the base plate. Spacers 32 support the wafer on the base plate. Referring now to FIG. 6B, force 36 is applied to the compression platform 34 to flatten the topmost conductive balls 14 within the through-hole vias of the wafer 10 on the base plate 30. Next, the wafer 10 is inverted and the spacers 32 are removed, as shown in FIG. 6C. The top surface 31, facing the compression platform 34 in the first stage, is now facing the base plate 30. In the second stage, shown in FIG. 6C, the bottom most conductive balls 14 are flattened by the force 36 applied to the compression platform 34. FIG. 6D illustrates the completed wafer 10 having filled vias 18. As above, the flattening of the conductive balls may be performed at room or elevated temperature, but below the melting temperature of the conductive balls.

A successful prototype has been produced in a single trial using a blank wafer of thickness 300 μm with multiple through-holes of 300 μm and eutectic SnPb solder balls. Optical photographs show the conductive balls filling the via after the flattening process.

Voids may be present between the conductive balls and the walls of the through-hole. But this is not deemed to present any reliability problem since (i) the through-silicon plug is subjected to little stress due to thermal cycling and (ii) the conductive metal would be impermeable to the wafer, thus not subject to explosive vapor expansion at high temperature and (iii) the formed plug and the wall of the through-hole are under a high magnitude of residue compressive stress from the mechanical compression. This not only prevents “extraction” of the plug from the through-hole, but also prevents transmission of stress to the void. Successive sequences of ball deposition and compression are needed in order to achieve the desired volume of protrusion.

While the invention has been particularly shown and described with reference to the preferred embodiments thereof, it will be understood by those skilled in the art that various changes in form and details may be made without departing from the spirit and scope of the invention.

What is claimed is:

1. A method of interconnection comprising:
providing a wafer having at least one through-hole therein;
filling said at least one through-hole with one or more conductive balls; and
thereafter compressing said wafer wherein said one or more conductive balls form a conductive plug in said at least one through-hole.

2. The method of claim 1 wherein said at least one through-hole has chamfered sidewalls.

3. The method of claim 1 wherein said at least one through-hole has a diffusion barrier layer on its sidewalls.

4. The method of claim 1 wherein said filling of said at least one through-hole is by a shake and drop technique.

5. The method of claim 1 wherein one or more of said conductive balls comprise deformable metals comprising solder, copper, or silver, or any material or composite that is conductive and deformable.

6. The method of claim 1 wherein at least two conductive balls are deposited into said at least one through-hole and wherein one of said conductive balls comprises a hard metal and another of said conductive balls comprises a deformable material.

7. The method of claim 1 wherein said compressing said wafer is performed in a mechanical compression device.

8. The method of claim 1 wherein said compressing said wafer is performed at a temperature of room temperature or above room temperature wherein said temperature is below a melting temperature of said one or more conductive balls.

9. The method of claim 1 wherein said conductive plug fills a volume lesser than, equal to, or greater than a volume of said at least one through-hole.

10. The method of claim 1 wherein said conductive plug has a depression or a protrusion formed in one or both ends of said through-hole.

11. The method of claim 10 wherein said compressing is performed by a mechanical compression device having a top and a bottom compression platform and wherein said depression or protrusion is shaped by said top or bottom compression platform.

12. The method of claim 1 wherein said through-hole is filled with at least two conductive balls wherein a top most conductive ball is adjacent to a top surface of said wafer and wherein a bottom most conductive ball is adjacent to a bottom surface of said wafer and wherein said compressing comprises two stages comprising:
placing said wafer onto a base plate of a compression device wherein said top surface of said wafer faces said base plate, wherein said top most conductive ball touches said base plate, and wherein spacers are placed to bridge a gap between said top surface of said wafer and said base plate;
placing a compression platform over said bottom surface of said wafer and applying force to said wafer whereby said bottom most conductive ball is flattened;
thereafter, removing said spacers and inverting said wafer so that said bottom surface faces said base plate and said top surface faces said compression platform; and
thereafter applying force to said wafer whereby said top most conductive ball is flattened to form said conductive plug.

13. The method of claim 1 further comprising stacking said wafer having said conductive plug in said at least one through-hole onto a correspondingly plugged second wafer or wafers.

14. The method of claim 13 further comprising singulating stacked said wafer and second wafer or wafers into chips.

15. The method of claim 1 further comprising:
cutting said wafer having said conductive plug;
mounting chips to said wafer to form a sub-module; and
stacking said sub-module onto correspondingly plugged second sub-module or sub-modules to form a three-dimensional system.

16. The method of claim 1 wherein said filling said at least one through-hole and said compressing said wafer is performed in successive sequence so as to achieve a desired aspect ratio.

17. The method of claim 1 further comprising post heating said wafer after formation of said conductive plug.

18. The method of claim 17 wherein said post heating is performed below a melting temperature of any of the materials of said conductive plug or above a melting temperature of one or more materials of said conductive plug.

19. The method of claim 13 further comprising post heating stacked said wafer and second wafer or wafers.

20. A method of forming a three-dimensional system comprising:
providing a first wafer and one or more second wafers each having at least one through-hole therein;
filling said at least one through-hole of each wafer with one or more conductive balls;
thereafter compressing each of said wafers wherein said one or more conductive balls form a conductive plug in said at least one through-hole of each of said wafers; and
thereafter joining said first wafer and said one or more second wafers.

21. The method of claim 20 wherein said first and second wafers have leveled conductive plugs and wherein said joining is achieved by depositing an additional volume of conductive material onto one end of each of said conductive plugs to be joined.

22. The method of claim 20 wherein said first and second wafers have protruding conductive plugs and wherein said joining is achieved by mechanical compression.

23. A mechanical compression device comprising:
a top and a bottom compression platform; and
means for compressing a wafer between said top and bottom compression platforms wherein said top and bottom compression platforms are shaped to form a depression or a protrusion on a top or bottom of a conductive plug formed in a through-hole in said wafer.
